(19) United States
(12) Patent Application Publication
(10) Pub. No.: US 2026/0228397 A1
(43) Pub. Date: Aug. 6, 2026

(54) Assessing Hazardous Behavior of Automated Vehicles Using Hidden Markov Models

(71) Applicant: Robert Bosch GmbH, Stuttgart (DE)

(72) Inventor: Armin Reisgys, Aichach (DE)

(21) Appl. No.: 19/463,867

(22) Filed: Jan. 29, 2026

(30) Foreign Application Priority Data
Feb. 5, 2025 (DE) 10 2025 104 285.3

(51) Int. Cl. G06F 30/27; G06F 30/15

(52) U.S. Cl. CPC G06F 30/27; G06F 30/15

(57) ABSTRACT

A method for assessing the safety of a vehicle or vehicle component includes accessing a state model for the vehicle or vehicle component. The state model is based on a hidden Markov model (HMM). The hidden states of the HMM represent safe and unsafe states of the vehicle or vehicle component. Observations of the HMM include observable events regarding the vehicle or vehicle component. The method further includes accessing a time series of data for a vehicle or vehicle component. The time series of data contains determined values for the observable parameters. The method also includes estimating probabilities of occurrence of the unsafe states of the vehicle or vehicle component using the HMM and the time series of data.

This application claims priority under 35 U.S.C. § 119 to patent application no. DE 10 2025 104 285.3, filed on Feb. 5, 2025 in Germany, the disclosure of which is incorporated herein by reference in its entirety.

### BACKGROUND

Partially or fully automated vehicles, or their functions, must be tested for safety extensively prior to being used in the field (the term “safety” is used in the present disclosure in the meaning of the English term “safety,” i.e., the operational safety of a vehicle or vehicle component).

The term “SOTIF” (Safety Of The Intended Functionality) plays a major role in the area of safety of road vehicles. As the name-giving standard, ISO 21448 describes a systematic approach that achieves the safety of the intended function, thus setting a standard for technical systems within the automotive industry. SOTIF focuses on the indeterminate question of how to specify, develop, verify, and validate a desired function so that it can be considered sufficiently safe.

When evaluating SOTIF for a vehicle with automated driving mode (AD) or a vehicle component of such a vehicle, the goal is to identify hazardous vehicle behaviors that may occur due to limitations or errors in the implemented functionality.

In order to find dangerous vehicle behaviors, there are several approaches in prior art. Scenario-based analysis creates a set of scenarios that represent different driving situations and conditions. These scenarios can include both normal and exceptional situations. By analyzing the behavior of the vehicle in these scenarios, potentially hazardous behaviors can be identified.

Other examples include Failure Mode and Effect Analysis (FMEA) and Failure Tree Analysis (FTA). FMEA (an inductive technique) and FTA (a deductive technique) are analyses that model the safety effects of a failure in a component or function on the system containing the component. The effects of system behavior may identify hazardous behaviors of the vehicle.

In addition, simulations and tests may be used to evaluate vehicle behavior under different conditions and scenarios. By performing various tests and simulations on the vehicle, potential hazardous behaviors can be observed and analyzed.

Furthermore, expert knowledge and experience can be harnessed. This enables vehicular safety experts to provide valuable insights and knowledge based on their experience. They may identify potential hazardous behaviors based on their understanding of the intended functionality of the vehicle and the possible limitations or failures that may occur.

The prior art approaches cannot be automated to a large extent in several examples. Additionally (and as a result), it may be difficult or even impossible to investigate large amounts of test data for the occurrence of unsafe or hazardous situations.

### SUMMARY

A first general aspect of the present disclosure relates to a method for assessing the safety of a vehicle or vehicle component. The method comprises accessing a state model for the vehicle or vehicle component. The state model is based on a hidden Markov model, HMM. The hidden states of the HMM represent safe and unsafe states of the vehicle or vehicle component. Observations of the HMM include observable events regarding the vehicle or vehicle component. The method further comprises accessing a time series of data for a vehicle or vehicle component. The time series of data contains determined values for the observable parameters. The method further comprises estimating probabilities of occurrence of the unsafe states of the vehicle or vehicle component using the HMM and the time series of data.

A second general aspect of the present disclosure relates to a method for training a state model for a vehicle or vehicle component. The method comprises accessing a state model for the vehicle or vehicle component. The state model is based on a hidden Markov model, HMM. Hidden states of the HMM represent safe and unsafe states of the vehicle or vehicle component. Observations of the HMM include observable events regarding the vehicle or vehicle component. The method further comprises accessing a first time series of data for a vehicle or vehicle component containing the observable events and accessing a second time series of safe and unsafe states of the vehicle or vehicle component associated with the first time series and configuring the parameters of the HMM based on the first and second time series.

A third general aspect of the present disclosure relates to an environment designed to perform a method according to the first or second general aspect (in particular, a test and/or development environment for vehicles or vehicle components).

A fourth general aspect of the present disclosure relates to a computer program containing commands that, when executed by a computer system, cause the computer system to perform the method according to the first or second general aspects.

A fifth general aspect of the present disclosure relates to a signal or a computer program product, which codes/contains a computer program according to the fourth general aspect.

The techniques of the first to fifth general aspects can have one or more of the following advantages in some cases.

Firstly, the HMM may automatically examine travel data for the (probable) occurrence of hazardous states of the vehicle or vehicle component. With some of the prior art methods, such automated investigation (and detection) is not possible. This may significantly accelerate testing of a vehicle or vehicle component in some cases.

Secondly, and subsequently, a greater amount of travel data may be investigated using the HMM than is possible with some prior art methods. Thus, in some examples, more reliable statements may be made regarding the safety of the vehicle or vehicle component. In particular, it may be possible to investigate rare hazardous driving situations.

Both of these may result in accelerated release and/or less resource-consuming design of a vehicle or vehicle component.

Some terms are used in the present disclosure as follows.

The descriptions of the HMMs in the present disclosure make use of commonly used terminology. Thus, hidden states refer to the states of the HMM that are not directly observable (e.g., “safe” and “unsafe”). The hidden states form the Markov chain that underlies the HMM. Accordingly, the observations of the HMM are the observable events (e.g., the measurable or otherwise determinable events) generated by the HMM. The techniques, by way of which the probabilities of occurrence of the hidden states can be estimated for a given HMM and given values for the observations, are known to a person skilled in the art and are therefore not explained in detail in the present disclosure.

An “event” may be any piece of data measured, calculated, and/or otherwise determined for the vehicle and/or vehicle component at a given time. For example, an event may be a value of an observable parameter of the vehicle or vehicle component at a given time (e.g., a steering angle or a speed). The particular time may be a time point or an interval (e.g., the value may be an average). The event may be determined from a plurality of observable parameters and/or may be a piece of data generated by processing observed parameters (e.g., a value of a signal in a vehicle component generated based on signals from one or more sensors).

The “safe” or “unsafe states” of a vehicle or vehicle component may be determined according to any predetermined safety rule or safety metric and/or based on expertise. The “unsafe states” of a vehicle or vehicle component, in some examples, describe a state of the vehicle or vehicle component in which there is an increased risk of damage to the vehicle or vehicle component, occupants of the vehicle, and/or the environment of the vehicle or vehicle component. In an illustrative and concrete example, an unsafe state may be defined as unintentionally crossing a lane boundary. The unsafe states for a vehicle component may be those states, in which a malfunction creates an unsafe state for the vehicle containing the vehicle component. In one illustrative and concrete example, an unsafe state of a camera-based component for monitoring the surrounding area may be that an object located in the area surrounding the vehicle containing the component is not detected.

A “vehicle” is any device that moves and can be used to carry passengers and/or loads. In some examples, a vehicle is a land vehicle, such as a passenger vehicle or a delivery truck. However, vehicles may also be (sub)marine vehicles, aircraft, and/or space vehicles. A vehicle may be at least partially autonomous (e.g., an autonomous vehicle of levels 3-5). A vehicle may also be a moving robot.

A “vehicle component” is any module located in a vehicle and/or communicatively connected to the vehicle. A vehicle component provides one or more vehicle functions (for example, assisted or autonomous driving functions). For example, it may be a driver assistance system and/or an autonomous driving component (or a subcomponent of those components).

The terms “vehicle” and “vehicle component” are not limited to the final product of a development process (i.e., the corresponding systems deployed or sold in the field). Rather, the terms encompass all stages of the development process of the final products. For example, a “vehicle” or “vehicle component” may be a model of a corresponding final product (e.g., a digital model).

A vehicle component may be a software component (i.e., the functionality of the vehicle component is defined in software) or may include a software subcomponent (e.g., in addition to sensors and/or actuators).

The term “validation” in the present disclosure encompasses any testing of a vehicle or vehicle component, to check whether set performance objectives are met and/or set requirements regarding its characteristics are met. In particular, these performance objectives and/or requirements may be performance objectives and/or requirements regarding the safety of the vehicle or vehicle component.

### BRIEF DESCRIPTION OF THE DRAWINGS

FIG. 1 is a flow chart showing the methods of the present disclosure.

FIG. 2 is a schematic illustration of an exemplary HMM according to the present disclosure.

FIG. 3 schematically illustrates an environment, in which the methods of the present disclosure may be performed.

### DETAILED DESCRIPTION

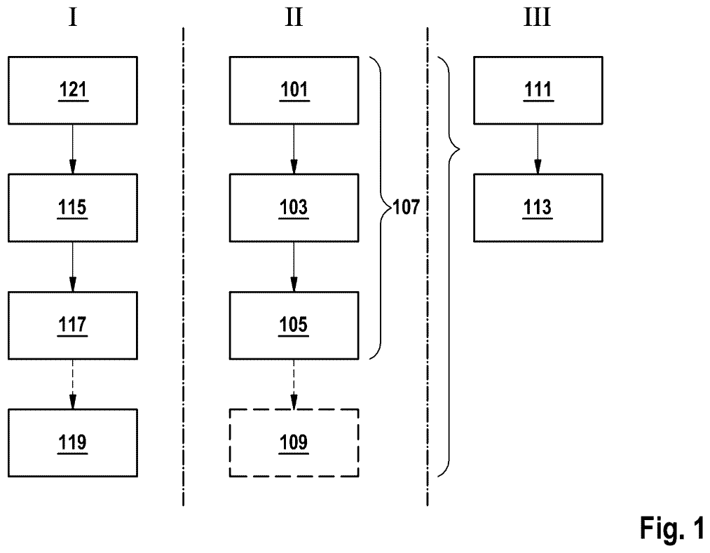

FIG. 1 is a flow chart showing the methods of the present disclosure. The middle column (II) schematically shows methods for assessing the safety of a vehicle or vehicle component.

The method includes accessing 101 a state model for the vehicle or vehicle component.

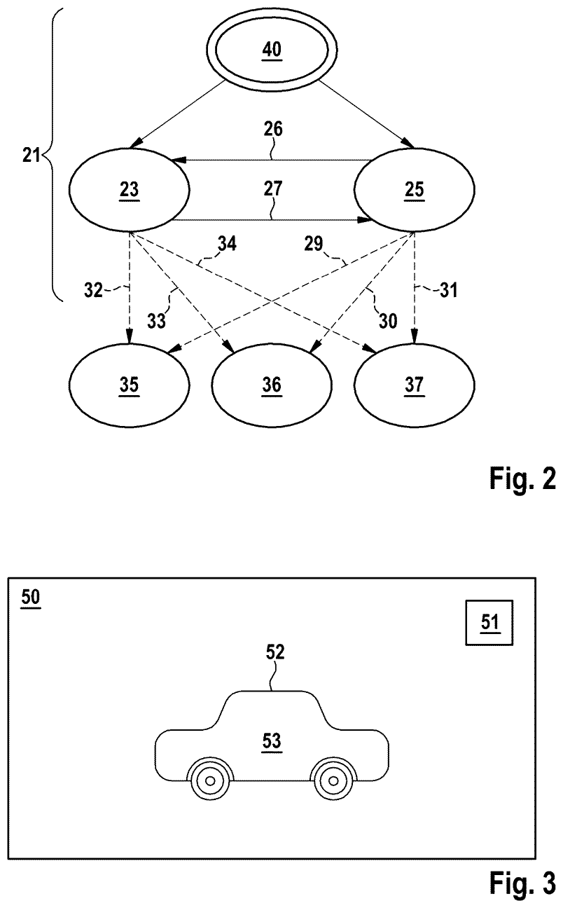

The state model is based on a hidden Markov model, HMM. Hidden states of the HMM represent safe and unsafe states of the vehicle or vehicle component (i.e., a first group of one or more hidden states of the HMM are unsafe states, and a second group of one or more hidden states of the HMM are safe states). Observations of the HMM include observable events regarding the vehicle or vehicle component. The HMM can model how a sequence of hidden states generates the observed events. In a specific example, an unsafe state may generate a first event with a first probability, a second event with a second probability (and, optionally, further events with further probabilities). The same applies to a safe state, which generates the first event with a first probability, a second event with a second probability (and, if necessary, further events, with further probabilities, wherein the probabilities at least partially differ). Further aspects of the HMM will be discussed further below with respect to FIG. 2.

The method further comprises accessing 103 a time series of data for a vehicle or vehicle component. The time series of data contains determined values for the observable events. In other words, the time series contains real values for the observations of the HMM. The data may include vehicle travel data or vehicle component operational data. In some examples, the data includes measurement data that was accessed and/or measured on the vehicle or vehicle component during operation (e.g., while traveling). In some examples, the method comprises determining (e.g., measuring the data).

The data may include any data that is detectable during operation of the vehicle or vehicle component. For example, the data may comprise sensor data or internal signals (e.g., generated in the vehicle or vehicle component based on sensor data). The sensors may include steering angle sensors, braking force sensors, distance sensors, accelerometers, force sensors, temperature sensors, cameras, or other imaging sensors (e.g., radar sensors, lidar sensors, or ultrasonic sensors) or any other types of sensors that may be used in a vehicle.

In some examples, the data contains synthesized data.

In some examples, the data has been collected in the field or on a test bench. Additionally, or alternatively, the data may be generated from simulations.

In general, the data has been collected prior to performing the methods for assessing the safety of a vehicle or vehicle component in accordance with the present disclosure. In other words, the assessment is not in real time. The assessment methods according to the present disclosure are generally not methods for assessing a current state of a particular vehicle or particular vehicle component in the field. Rather, the methods according to the present disclosure are performed as part of a development process of the vehicle or vehicle component (e.g., as part of a validation, as described in more detail below).

The method comprises estimating 105 probabilities of occurrence of the unsafe states of the vehicle or vehicle component using the HMM and the time series of data.

In some examples, estimating probabilities of occurrence comprises estimating a frequency of occurrence of the unsafe states and/or the duration of occurrence of the unsafe states assuming that HMM generates the determined values of the time series (e.g., during a time period that the time series covers).

For example, estimating the probabilities of occurrence may include determining a sequence of hidden states that matches the time series of data. In some examples, determining a sequence may include determining hidden states that have the highest probability of resulting in the time series of data in the HMM (e.g., a sequence of safe and unsafe states of the vehicle or vehicle component). Additionally, or alternatively, estimating the probabilities of occurrence may include determining discrete hidden states that fit certain values in the time series data (e.g., discrete hidden states that have the highest probability of generating the determined values as observations of the HMM).

The estimation of probabilities of occurrence may comprise one or more instances of determining when and/or how often a probability of occurrence for unsafe states is above a particular threshold.

In some examples, the method for assessing the safety of a vehicle or vehicle component for a particular vehicle or vehicle component may be performed multiple times. For example, different time series and data (e.g., time series recorded during different test runs or simulations) may be analyzed in the different runs with the HMM.

In some examples, for a vehicle or vehicle component, the methods for assessing the safety of the vehicle or vehicle component may be performed multiple times with different HMMs each representing safe and unsafe states of the vehicle or vehicle component (and for which observations differ in some examples). The various HMMs may represent various predetermined safety rules or safety metrics or expertise.

The methods of the present disclosure (and, in particular, the methods for assessing the safety of a vehicle or vehicle component and the methods for validation) may be performed automatically in some examples (i.e., without human interaction other than starting and/or confirming operations).

In some examples, validation of the vehicle or vehicle component may be performed based on the estimated probability of occurrence. The present disclosure also relates to a method for validating a vehicle or vehicle component. The method comprises performing 107 a method for assessing the safety of a vehicle or vehicle component in accordance with the present disclosure (e.g., multiple times with different time series of data) and validating 109 of the vehicle or vehicle component based on the estimated probabilities of occurrence of the unsafe and/or safe states.

In some examples, the vehicle or vehicle component is not released (e.g., to enter a further step of a development process and/or to implement into a product) when the estimated probabilities of occurrence of the unsafe states are above a threshold value. For example, the threshold value may establish a maximum frequency and/or a maximum duration of occurrence of the unsafe states.

Additionally, or alternatively, the vehicle or vehicle component may be released (e.g., to enter a further step of a development process and/or to implement into a product) if the estimated probabilities of occurrence of the unsafe states are below a threshold value. For example, the threshold value may establish a maximum frequency and/or a maximum duration of occurrence of the unsafe states.

The present disclosure also relates to methods for manufacturing a vehicle or vehicle component. Exemplary methods for manufacturing a vehicle or vehicle component are shown in the right column (III) of FIG. 1. The method comprises performing 111 one of the methods for validating a vehicle or vehicle component according to the present disclosure and manufacturing 113 a vehicle or vehicle component after validation has been completed.

Manufacturing can be any act by which an operable product is produced. For example, in instances where the vehicle component is a software component or the vehicle contains a vehicle component in the form of a software component, manufacturing may include uploading the software component to the vehicle or any of its parts (e.g., via over-the-air updates).

The present disclosure also relates to methods for implementing the vehicle or vehicle component, comprising performing one of the methods for manufacturing a vehicle or vehicle component according to the present disclosure and utilizing the manufactured vehicle or vehicle component.

FIG. 2 shows a schematic illustration of an exemplary HMM 20 according to the present disclosure.

As already explained, the HMM 20 contains a plurality of states 21. The states 21 include safe states 23 and unsafe states 25. In other words, each safe state 23 depicts or models a safe state of the vehicle or vehicle component. With each unsafe state 25, an unsafe state of the vehicle or vehicle component (a hazardous state) is depicted or modeled. As described above, the safe and unsafe states may be determined according to any predetermined safety rule or safety metric and/or based on expertise.

In some examples, the HMM 20 has exactly one hidden unsafe state 25. Alternatively, the HMM may have more than one hidden unsafe state. Additionally, or alternatively, the HMM 20 has exactly one hidden safe state 23. Alternatively, the HMM may have more than one hidden safe state.

In some examples, the HMM 20 includes a starting state 40.

The HM 20 additionally contains several observations 35, 36, 37. The observations 35, 36, 37 of the HMM 20 contain observable events regarding the vehicle or vehicle component. In other words, the HMM 20 models, in the observations 35, 36, 37, that the respective observable events occur with respect to the vehicle or vehicle component.

Additionally, the HMM 20 may include transition probabilities 26, 27 among the hidden states 23, 25. The transition probabilities 26, 27 among the hidden states 23, 25 indicate the probability of switching from a first to a second hidden state.

Additionally, the HMM 20 may contain transition probabilities 29-34 between the hidden states 23, 25 and the observations. The transition probabilities 29-34 between the hidden states 23, 25 and the observations indicate the probability of generating a particular observation 29-34 from a particular hidden state 23, 25 (i.e., the probability of making a particular observation when the vehicle or vehicle component is in a particular hidden state). For example, the transition probability 29 indicates the probability generating the first observation 35 from the hidden unsafe state.

By way of techniques known to a skilled person, an associated or appropriate sequence of safe and unsafe states can be determined for a particular sequence of observations. In this manner, the HMM 20 allows time series of data for the vehicle or vehicle component to be indicative of the probability of the vehicle or vehicle component having been in an unsafe state while recording the time series.

The left column (I) schematically shows methods for training a state model for a vehicle or vehicle component. The present disclosure also relates to methods for training a state model to assess the safety of a vehicle or vehicle component.

The method comprises accessing 121 a state model for a vehicle or vehicle component. The state model is based on a hidden Markov model, HMM. Hidden states of the HMM represent safe and unsafe states of the vehicle or vehicle component. Observations of the HMM include observable events regarding the vehicle or vehicle component.

The method further comprises accessing 115 a first time series of data for a vehicle or vehicle component containing the observable events and accessing 117 a second time series of safe and unsafe states of the vehicle or vehicle component associated with the first time series. The method further comprises configuring 119 the parameters of the HMM based on the first and second time series.

In some examples, the parameters of the HMM include transition probabilities among the hidden states and between the hidden states and the observations.

In some examples, the second time series may be generated at least partially manually (e.g., by an expert).

The HMM can be designed by using techniques known to a person skilled in the art for determining the parameters of HMMs.

After training, the trained state model may be employed in the methods for assessing the safety of a vehicle or vehicle component according to the present disclosure.

FIG. 3 schematically illustrates an environment 50, in which the methods of the present disclosure may be performed.

Generally, the environment 50 comprises a computer system 51 with at least one computing unit and corresponding memory. The computer system 51 is configured to perform a method according to the present disclosure. Depending on the nature of the method, the computer system may be configured differently. The construction of the computer system can be arbitrary in this context. In some examples, the computer system is distributed across multiple computing units. The computer system may comprise remote servers and/or comprise a cloud computing system.

In some examples, the environment is a test and/or development environment for vehicles 52 or vehicle components 53. The vehicle 52 or vehicle component 53 may be present in the test and/or development environment as a model. In other examples, the vehicle component 53 is a software component or contains a software subcomponent (which defines functionality of the vehicle component). The test and/or development environment may include a simulation environment, in which the vehicle 52 or vehicle component 53 may be tested.

The present disclosure also relates to a computer program containing commands that, when executed by a computer system, cause the computer system to perform the methods according to the present disclosure.

The present disclosure also relates to a signal product that codes a computer program according to the present disclosure.

The present disclosure also relates to a computer program product containing a computer program according to the present disclosure.

What is claimed is:

1. A method for assessing safety of a vehicle or vehicle component, comprising:
accessing a state model for the vehicle or vehicle component, wherein (i) the state model is based on a hidden Markov model (HMM), (ii) hidden states of the HMM represent safe and unsafe states of the vehicle or vehicle component, and (iii) observations of the HMM contain observable events regarding the vehicle or vehicle component;
accessing a time series of data for the vehicle or vehicle component, wherein the time series of data contains determined values for the observable events; and
estimating probabilities of occurrence of the unsafe states of the vehicle or vehicle component using the HMM and the time series of data.

2. The method according to claim 1, wherein estimating probabilities of occurrence comprises estimating a frequency of occurrence of the unsafe states and/or the duration of occurrence of the unsafe states assuming that the HMM generates the determined values of the time series.

3. The method of claim 1, wherein estimating the probabilities of occurrence includes determining a sequence of hidden states that matches the time series of data in the HMM.

4. The method according to claim 1, wherein the HMM has exactly one hidden unsafe state, and/or wherein the HMM has exactly one hidden safe state.

5. A method for validating a vehicle or vehicle component, comprising:
performing the method according to claim 1; and
validating the vehicle or vehicle component based on the estimated probabilities of occurrence of the unsafe and/or safe states.

6. The method according to claim 5, wherein the vehicle or vehicle component is not released if the estimated probabilities of occurrence of the unsafe states are above a threshold value.

7. A method for manufacturing a vehicle or vehicle component, comprising:
performing the method according to claim 5; and
manufacturing a vehicle or vehicle component after validation has been completed.

8. A method for training a state model to assess safety of a vehicle or vehicle component, comprising:
accessing a state model for the vehicle or vehicle component, wherein (i) the state model is based on a hidden Markov model (HMM), (ii) hidden states of the HMM represent safe and unsafe states of the vehicle or vehicle component, and (iii) observations of the HMM contain observable events regarding the vehicle or vehicle component,
accessing a first time series of data for a vehicle or vehicle component that contains determined values for the observable events;
accessing a second time series of safe and unsafe states of the vehicle or vehicle component associated with the first time series; and
configuring the parameters of the HMM based on the first and second time series.

9. The method according to claim 8, wherein the parameters of the HMM contain transition probabilities among the hidden states, and between the hidden states and the observations.

10. An environment designed to perform the method according to claim 1, wherein the environment is a test and/or development environment for vehicles or vehicle components.

11. A computer program containing commands that, when executed by a computer system, cause the computer system to perform the method according to claim 1.

12. A signal or computer program product coding/containing the computer program according to claim 11.

13. The method of claim 1, wherein estimating the probabilities of occurrence includes determining a sequence of hidden states that has the highest probability of resulting in the time series of data in the HMM.
